(19) United States
(12) Patent Application Publication
(10) Pub. No.: US 2008/0078441 A1
(43) Pub. Date: Apr. 3, 2008

(54) SEMICONDUCTOR DEVICES AND METHODS FROM GROUP IV NANOPARTICLE MATERIALS

(76) Inventors: Dmitry Poplavskyy, San Jose, CA (US); Homer Antoniadis, Mountain View, CA (US); David Jurbergs, Austin, TX (US); Maxim Kelman, Mountain View, CA (US); Francesco Lemmi, Sunnyvale, CA (US); Pingrong Yu, Sunnyvale, CA (US)

Correspondence Address: FOLEY & LARDNER LLP, 150 EAST GILMAN STREET, P.O. BOX 1497, MADISON, WI, 53701-1497, US

(21) Appl. No.: 11/857,854

(22) Filed: Sep. 19, 2007

Related U.S. Application Data
(60) Provisional application No. 60/848,328, filed on Sep. 28, 2006.

(51) Int. Cl. H01L 31/00; H01L 21/02

(52) U.S. Cl. 136/255; 438/96; 257/E31.001; 257/E21.466

(57) ABSTRACT

A device for generating electricity from solar radiation is disclosed. The device includes a substrate; an insulating layer formed above the substrate; and a first electrode formed above the insulating layer. The device also includes a first doped Group IV nanoparticle thin film deposited on the first electrode; and a second doped Group IV nanoparticle thin film deposited on the first doped Group IV nanoparticle thin film. The device further includes a third doped Group IV nanoparticle thin film deposited on the second doped Group IV nanoparticle thin film; a fourth doped Group IV nanoparticle thin film deposited on the third doped Group IV nanoparticle thin film; and, a second electrode formed on the fourth doped Group IV nanoparticle thin film. Wherein, when solar radiation is applied to the fourth doped Group IV nanoparticle thin film, an electrical current is produced.

### CROSS-REFERENCE TO RELATED APPLICATIONS

This application claims the benefit of U.S. Provisional Patent Application Ser. No. 60/848,328 filed Sep. 28, 2006, the entire disclosure of which is incorporated by reference. The following commonly-assigned U.S. patent applications are co-pending with this application: (1) Photoconductive Devices with Enhanced Efficiency from Group IV Nanoparticle Materials and Methods Thereof (filed Sep. 19, 2007); (2) Group IV Nanoparticles and Films Thereof (Ser. No. 11/842,466; filed Aug. 21, 2007); (3) Fullerene-Capped Group IV Semiconductor Nanoparticles and Devices Made Therefrom (Ser. No. 11/844,827; filed Aug. 24, 2007); and (4) Semiconductor Thin Films Formed from Group IV Nanoparticles (Ser. No. 11/851,004; filed Sep. 6, 2007). The entire disclosures of these applications are incorporated herein by reference.

### FIELD OF DISCLOSURE

This disclosure relates to photoconductive thin film devices fabricated using Group IV semiconductor nanoparticles, and methods for fabrication and use of such devices.

### BACKGROUND

The Group IV semiconductor materials enjoy wide acceptance as the materials of choice in a range devices in numerous markets such as communications, computation, and energy. Currently, particular interest is aimed in the art at improvements in devices utilizing semiconductor thin film technologies due to the widely recognized disadvantages of the current chemical vapor deposition (CVD) technologies. For example, some of the drawbacks of CVD technologies include, the high production of chemical wastes; the difficulty in accommodating large components, and high processing temperatures.

In that regard, with the emergence of nanotechnology, there is in general growing interest in leveraging the advantages of these new materials in order to produce low-cost devices with designed functionality using high volume manufacturing on nontraditional substrates. It is therefore desirable to leverage the knowledge of Group IV semiconductor materials and at the same time exploit the advantages of Group IV semiconductor nanoparticles for producing novel thin films, which may be readily integrated into a number of devices. Particularly, Group IV nanoparticles in the range of between about 1.0 nm to about 100.0 nm may exhibit a number of unique electronic, magnetic, catalytic, physical, optoelectronic, and optical properties due to quantum confinement and surface energy effects.

With respect to thin films compositions utilizing nanoparticles, U.S. Pat. No. 6,878,871 describes photovoltaic devices having thin layer structures that include inorganic nanostructures, optionally dispersed in a conductive polymer binder. Similarly, U.S. Patent Application Publication No. 2003/0226498 describes semiconductor nanocrystal/conjugated polymer thin films, and U.S. Patent Application Publication No. 2004/0126582 describes materials comprising semiconductor particles embedded in an inorganic or organic matrix. Notably, these references focus on the use of Group II-VI or III-V nanostructures in thin layer structures, rather than thin films formed from Group IV nanostructures.

In U.S. Patent Application Publication No. 2006/0154036, composite sintered thin films of Group IV nanoparticles and hydrogenated amorphous Group IV materials are discussed. The Group IV nanoparticles are in the range 0.1 nm to 10 nm, in which the nanoparticles were passivated, typically using an organic passivation layer. In order to fabricate thin films from these passivated particles, the processing was performed at 400° C., where nanoparticles below 10 nm are used to lower the processing temperature. In this example, significant amounts of organic materials are present in the Group IV thin film layers, and the composites formed are substantially different than the well-accepted native Group IV semiconductor thin films.

U.S. Pat. No. 5,576,248 describes Group IV semiconductor thin films formed from nanocrystalline silicon and germanium of 1.0 nm to 100.0 nm in diameter, where the film thickness is not more than three to four particles deep, yielding film thickness of about 2.5 nm to about 20 nm. However, for many electronic and photoelectronic applications, Group IV semiconductor thin films of about 50 nm to 3 microns are desirable.

Therefore, there is a need in the art for devices made from native Group IV semiconductor thin films, where the films are about 200 nm to 3 microns in thickness fabricated from Group IV semiconductor nanoparticles, which thin films are readily made using high volume processing methods.

### SUMMARY

The invention relates, in one embodiment, to a device for generating electricity from solar radiation. The device includes a substrate; an insulating layer formed above the substrate; and a first electrode formed above the insulating layer. The device also includes a first doped Group IV nanoparticle thin film deposited on the first electrode; and a second doped Group IV nanoparticle thin film deposited on the first doped Group IV nanoparticle thin film. The device further includes a third doped Group IV nanoparticle thin film deposited on the second doped Group IV nanoparticle thin film; a fourth doped Group IV nanoparticle thin film deposited on the third doped Group IV nanoparticle thin film; and, a second electrode formed on the fourth doped Group IV nanoparticle thin film. Wherein, when solar radiation is applied to the fourth doped Group IV nanoparticle thin film, an electrical current is produced.

The invention relates, in another embodiment, to a method of manufacturing a device for generating electricity from solar radiation. The method includes providing a substrate; forming an insulating layer above the substrate; and forming a first electrode above the insulating layer. The method also includes depositing a first doped Group IV nanoparticle thin film on the first electrode; and depositing a second doped Group IV nanoparticle thin film on the first doped Group IV nanoparticle thin film. The method further includes depositing a third doped Group IV nanoparticle thin film on the second doped Group IV nanoparticle thin film; depositing a fourth doped Group IV nanoparticle thin film on the third doped Group IV nanoparticle thin film; and forming a second electrode on the fourth doped Group IV nanoparticle thin film.

### BRIEF DESCRIPTION OF THE DRAWINGS

FIG. 1A-FIG. 1E depict a process for fabricating an embodiment of a single junction photoconductive thin film device using Group IV semiconductor nanoparticles.

FIG. 2A-FIG. 2E depict another process for fabricating an embodiment of a photoconductive thin film device using Group IV semiconductor nanoparticles.

FIG. 3 is a scanning electron micrograph (SEM) showing the cross-section of a two-layer Group IV semiconductor thin film.

FIG. 4 is another embodiment of a single junction photoconductive thin film device using Group IV semiconductor nanoparticles.

FIG. 5 is a cross-section of an embodiment of a tandem photoconductive structure fabricated using Group IV semiconductor nanoparticles.

FIG. 6 is a cross-section of another embodiment of a tandem photoconductive structure fabricated using Group IV semiconductor nanoparticles.

FIG. 7 is a cross-section of still another embodiment of a tandem photoconductive structure fabricated using Group IV semiconductor nanoparticles.

FIG. 8A and FIG. 8B are cross-sections of two additional embodiments of photoconductive structures fabricated using Group IV semiconductor nanoparticles.

FIG. 9 is a cross-section of an additional embodiment of a tandem photoconductive structure fabricated using Group IV semiconductor nanoparticles.

FIG. 10 is a depiction of a high-volume batch process for the deposition of Group IV semiconductor nanoparticle thin films using embodiments of Group IV semiconductor nanoparticle inks.

FIG. 11 is a depiction of a high-volume web process for the deposition of Group IV semiconductor nanoparticle thin films using embodiments of Group IV semiconductor nanoparticle inks.

### DETAILED DESCRIPTION

Embodiments of devices formed from native Group IV semiconductor thin films, and methods for making such devices are disclosed herein. The thin films are formed from coating substrates using dispersions of Group IV nanoparticles, and processing the coated particle films to form photoconductive thin films from which devices are fabricated.

The embodiments of the disclosed photoconductive thin film devices fabricated from Group IV semiconductor nanoparticles starting materials evolved from the inventors' observations that by keeping embodiments of the native Group IV semiconductor nanoparticles in an inert environment from the moment they are formed through the formation of Group IV semiconductor thin films, that such thin films so produced have properties characteristic of native bulk semiconductor materials. In that regard, the photoconductive devices that are then fabricated from such thin films are formed from materials for which the electrical, spectral absorbance and photoconductive properties are well characterized. This is in contrast, for example, to the use of modified Group IV semiconductor nanoparticles, which modifications generally use organic species to stabilize the reactive particles, or mix the nanoparticles with organic modifiers, or both. In some such modifications, the Group IV nanoparticle materials are significantly oxidized. The use of these types of nanoparticle materials produces hybrid thin films, which hybrid thin films do not have as yet the same desirable properties as traditional Group IV semiconductor materials.

As used herein, the term “Group IV semiconductor nanoparticle” generally refers to hydrogen terminated Group IV semiconductor nanoparticles having an average diameter between about 1.0 nm to 100.0 nm, and composed of silicon, germanium, and alpha-tin, or combinations thereof. As will be discussed subsequently, some embodiments of thin film devices utilize doped Group IV semiconductor nanoparticles. With respect to shape, embodiments of Group IV semiconductor nanoparticles include elongated particle shapes, such as nanowires, or irregular shapes, in addition to more regular shapes, such as spherical, hexagonal, and cubic nanoparticles, and mixtures thereof. Additionally, the nanoparticles may be single-crystalline, or amorphous in nature. As such, a variety of types of Group IV semiconductor nanoparticle materials may be created by varying the attributes of composition, size, shape, and crystallinity of Group IV semiconductor nanoparticles. Exemplary types of Group IV semiconductor nanoparticle materials are yielded by variations including, but not limited by: 1) single or mixed elemental composition; including alloys, core/shell structures, doped nanoparticles, and combinations thereof 2) single or mixed shapes and sizes, and combinations thereof, and 3) single form of crystallinity or a range or mixture of crystallinity, and combinations thereof.

Regarding the terminology of the art for Group IV semiconductor thin film materials, the term “amorphous” is generally defined as noncrystalline material lacking long-range periodic ordering, while the term “polycrystalline” is generally defined as a material composed of crystallite grains of different crystallographic orientation, where the amorphous state is either absent or minimized (e.g. within the grain boundary and having an atomic monolayer in thickness). With respect to the term “microcrystalline”, in some current definitions, this represents a thin film having properties between that of amorphous and polycrystalline, where the crystal volume fraction may range between a few percent to about 90%. In that regard, on the upper end of such a definition, there is arguably a continuum between that which is microcrystalline and polycrystalline. For the purpose of what is described herein, “microcrystalline” is a thin film in which microcrystallites are embedded in an amorphous matrix, and “polycrystalline” is not constrained by crystallite size, but rather a thin film having properties reflective of the highly crystalline nature.

The Group IV semiconductor nanoparticles may be made according to any suitable method, several of which are known, provided they are initially formed in an environment that is substantially inert, and substantially oxygen-free. As used herein, “inert” is not limited to only substantially oxygen-free. It is recognized that other fluids (i.e., gases, solvents, and solutions) may react in such a way that they negatively affect the electrical and photoconductive properties of Group IV semiconductor nanoparticles. Additionally, the terms “substantially oxygen-free” in reference to environments, solvents, or solutions refer to environments, solvents, or solutions wherein the oxygen content has been substantially reduced to produce Group IV semiconductor thin films having no more than 10¹⁷ to 10¹⁹ oxygen per cubic centimeter of Group IV semiconductor thin film. For example, it is contemplated that plasma phase preparation of hydrogen-terminated Group IV semiconductor nanoparticles is done in an inert, substantially oxygen-free environment. As such, plasma phase methods produce nanoparticle materials of the quality suitable for making embodiments of Group IV semiconductor thin film devices. For example, one plasma phase method, in which the particles are formed in an inert, substantially oxygen-free environment, is disclosed in U.S. patent application Ser. No. 11/155,340, filed Jun. 17, 2005; the entirety of which is incorporated herein by reference.

It is contemplated that embodiments of doped Group IV semiconductor nanoparticles can be utilized to fabricate doped Group IV semiconductor thin film devices. In that regard, during plasma phase preparation, dopants can be introduced in to gas phase during the formation and growth of Group IV semiconductor nanoparticles. For example, n-type Group IV semiconductor nanoparticles may be prepared using a plasma phase method in the presence of well-known gases such as phosphorous oxychloride, phosphine, or arsine. Alternatively, p-type semiconductor nanoparticles may be prepared in the presence of boron diflouride, trimethyl borane, or diborane. For core/shell Group IV semiconductor nanoparticles, the dopant may be in the core or the shell or both the core and the shell.

After the preparation of quality Group IV semiconductor nanoparticles in an inert, substantially oxygen-free environment, the particles are formulated as dispersions or inks in an inert, substantially oxygen-free environment, so that they can be deposited on a solid support. In terms of preparation of the dispersions, the use of particle dispersal methods such as sonication, high shear mixers, and high pressure/high shear homogenizers are contemplated for use to facilitate dispersion of the particles in a selected solvent or mixture of solvents. For example, inert dispersion solvents contemplated for use include, but are not limited to chloroform, tetrachloroethane, chlorobenzene, xylenes, mesitylene, diethylbenzene, 1,3,5 triethylbenzene (1,3,5 TEB), and combinations thereof.

Various embodiments of Group IV semiconductor nanoparticle inks can be formulated by the selective blending of different types of Group IV semiconductor nanoparticles. For example, varying the packing density of Group IV semiconductor nanoparticles in a deposited thin layer is desirable for forming a variety of embodiments of Group IV photoconductive thin films. In that regard, Group IV semiconductor nanoparticle inks can be prepared in which various sizes of monodispersed Group IV semiconductor nanoparticles are specifically blended to a controlled level of polydispersity for a targeted nanoparticle packing. Further, Group IV semiconductor nanoparticle inks can be prepared in which various sizes, as well as shapes are blended in a controlled fashion to control the packing density.

Still another example of what may achieved through the selective formulation of Group IV semiconductor nanoparticle inks by blending doped and undoped Group IV semiconductor nanoparticles. For example, various embodiments of Group IV semiconductor nanoparticle inks can be prepared in which the dopant level for a specific thin layer of a targeted device design is formulated by blending doped and undoped Group IV semiconductor nanoparticles to achieve the requirements for that layer. In still another example are embodiments of Group IV semiconductor nanoparticle inks that may compensate for defects in embodiments of Group IV photoconductive thin films. For example, it is known that in an intrinsic silicon thin film, low levels of oxygen may act to create undesirable trap states. To compensate for this, low levels of p-type dopants, such as boron diflouride, trimethyl borane, or diborane, may be used to compensate for the presence of low levels of oxygen. By using Group IV semiconductor nanoparticles to formulate embodiments of inks, such low levels of p-type dopants may be readily introduced in embodiments of blends of the appropriate amount of p-doped Group IV semiconductor nanoparticles with various types of undoped Group IV semiconductor nanoparticles.

Other embodiments of Group IV semiconductor nanoparticle inks can be formulated that adjust the band gap of embodiments of Group IV photoconductive thin films. For example, the band gap of silicon is about 1.1 eV, while the band gap of germanium is about 0.7 eV, and for alpha-tin is about 0.05 eV. Therefore, formulations of Group IV semiconductor nanoparticle inks may be selectively formulated so that embodiments of Group IV photoconductive thin films may have photon adsorption across a wider range of the electromagnetic spectrum.

The thin film of deposited Group IV semiconductor nanoparticles is then fabricated into a Group IV semiconductor thin film. The fabrication steps are done in an inert, substantially oxygen free environment, using temperatures between about 300° C. to about 900° C. Heat sources contemplated for use include conventional contact thermal sources, such as resistive heaters, as well as radiative heat sources, such as lasers, and microwave processing equipment. More specifically, lasers operating in the wavelength range between 0.5 micron to 10 micron, and microwave processing equipment operating in even longer wavelength ranges are matched to the fabrication requirements of embodiments of Group IV semiconductor thin films described herein. These types of apparatuses have the wavelengths for the effective penetration the film thicknesses, as well as the power requirements for fabrication of such thin film devices.

Regarding the time required to fabricate a deposited Group IV nanoparticle thin film into a Group IV photoconductive thin film, the time required varies as an inverse function in relation to the processing temperature. For example, if the processing temperature is about 800° C., then for various embodiments of Group IV photoconductive thin films, the processing time may be, for example, between about 5 minutes to about 15 minutes. However, if the processing temperature is about 400° C., then for various embodiments of Group IV photoconductive thin films, the processing temperature may be between about, for example, 1 hour to about 10 hours. The fabrication process may also optionally include the use of pressure of between up about 7000 psig. The process of preparing Group IV semiconductor thin films from Group IV semiconductor nanoparticle materials has been described in US Provisional Application [App. Ser. No. 60/842,818], with a filing date of Sep. 7, 2006, and entitled, “Semiconductor Thin Films Formed from Group IV Nanoparticles.” The entirety of this application is incorporated by reference.

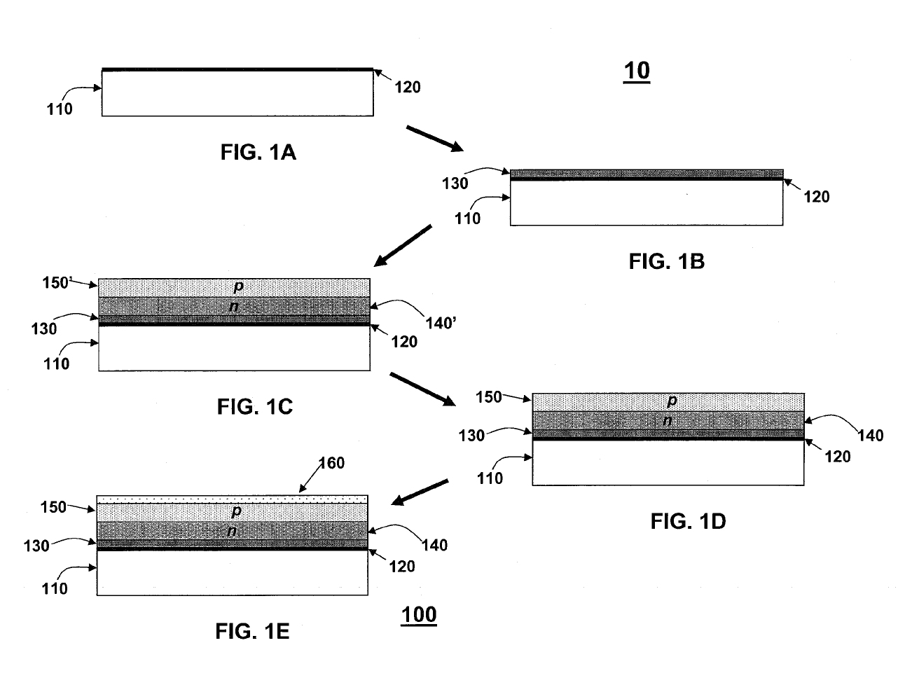

In FIG. 1E a single junction p/n device 100 is shown. What is shown in FIGS. 1A-1E is a first method 10 for making a single junction p/n device with embodiments of Group IV semiconductor nanoparticle materials. In method 10, the sequential deposition of embodiments of crystalline Group IV semiconductor nanoparticle thin films, followed by a fabrication step are done in which the nanoparticle thin films are processed to form embodiments a single p/n junction device 100.

For process 10, in FIG. 1A, the fabrication of device 100 is shown starting with substrate 110, upon which a first electrode, 130 (FIG. 1B), and optionally an insulating layer 120 between the substrate 110 and electrode 130 are deposited. For some embodiments of single junction p/n device 100, substrate materials may be selected from silicon dioxide-based substrates. Such silicon dioxide-based substrates include, but are not limited by, quartz, and glasses, such as soda lime and borosilicate glasses. For other embodiments of Group IV semiconductor single junction p/n device 100, flexible stainless steel sheet is the substrate of choice, while for still other embodiments of single junction p/n device 100, the substrate may be selected from heat-durable polymers, such as polyimides and aromatic fluorene-containing polyarylates, which are examples of polymers having glass transition temperatures above about 300° C. The first electrode 130 is selected from conductive materials, such as, for example, aluminum, molybdenum, chromium, titanium, nickel, and platinum. For various embodiments of photoconductive devices contemplated, the first electrode 130 is between about 10 nm to about 1000 nm in thickness. Optionally, an insulating layer 120 may be deposited on the substrate 110 before the first electrode 130 is deposited. Such an optional layer is useful when the substrate is a dielectric substrate, since it protects the subsequently fabricated Group IV semiconductor thin films from contaminants that may diffuse from the substrate into the Group IV semiconductor thin film during fabrication. When using a conductive substrate, the insulating layer 120 not only protects Group IV semiconductor thin films from contaminants that may diffuse from the substrate, but is required to prevent shorting. Additionally, an insulating layer 120 may be used to planarize an uneven surface of a substrate. The insulating layer 120 is selected from dielectric materials such as, for example, but not limited by, silicon nitride and alumina. For various embodiments of photoconductive devices contemplated the insulating layer 120 is about 5 nm to about 100 nm in thickness.

In FIG. 1C, after the first electrode, 130, and optionally an insulating layer 120 between the substrate 110 and electrode 130 have been deposited, a first Group IV nanoparticle film layer 140′ of the device 100 is deposited. This first crystalline Group IV semiconductor nanoparticle layer 140′ is deposited using an embodiment of a Group IV semiconductor n-doped nanoparticle ink, or the thin film is the subsequently n-doped using, for example, standard procedures for thin film doping with phosphine, arsine, or phosphorous oxychloride. Similarly, the second p-doped nanoparticle thin film layer 150′ is either deposited using an embodiment of a Group IV semiconductor p-doped nanoparticle ink, or the thin film is the subsequently p-doped using, for example, standard procedures for thin film doping with boron diflouride, trimethyl borane, or diborane. Alternatively, FIG. 1E could have the n-layer and p-layer reversed, so that the first deposited crystalline Group IV semiconductor nanoparticle layer 140′ would be deposited using an embodiment of a Group IV semiconductor p-doped nanoparticle ink, or the thin film is then subsequently p-doped. In such a Group IV photoconductive device, the second layer 150′ would then be deposited using a Group IV semiconductor n-doped nanoparticle ink, or the thin film is the subsequently n-doped.

Once the two layers 140′ and 150′ of Group IV semiconductor nanoparticles are formed, the nanoparticle thin films are processed in an inert, substantially oxygen free environment at between about 300° C. to about 900° C., for the appropriate length of time, as previously discussed, and optionally using pressure up to about 7000 psig. In FIG. 1D, the singe junction p/n photoconductive film formed is comprised of an n-doped Group IV semiconductor photoconductive thin film 140 and a p-doped photoconductive Group IV semiconductor thin film 150. Alternatively, as mentioned in the above, the singe junction p/n photoconductive film formed may be comprised of a p-doped Group IV semiconductor photoconductive thin film 140 and an n-doped photoconductive Group IV semiconductor thin film 150. The two thin films together are about between 0.1 microns to about 10 microns in thickness for many applications, but may be as thick as up to 100 microns for others. For various embodiments of device 100 of FIG. 1E, the n-doped and p-doped photoconductive Group IV semiconductor layers individually may vary depending on the application. For example, in some embodiments, 140 and 150 may be the same thickness, while in other embodiments the p-doped layer 140 may be between about 10% to about 20% of the thickness of the n-doped layer 150, while in still other embodiments, the n-doped layer 150 may be between about 10% to about 20% of the thickness of the p-doped layer 140.

Finally, in FIG. 1E, after the processing to form the p/n junction, a transparent conductive oxide (TCO) layer 160 is deposited on the p-doped layer. This not only provides a second electrode, but moreover allows a photo flux to penetrate to the photoconductive layers. Materials useful for the TCO layer 160 include, but are not limited by indium tin oxide (ITO), tin oxide (TO), and zinc oxide (ZnO). For various embodiments of photoconductive devices contemplated, the TCO layer is from about 100 nm to about 200 nm in thickness. Alternatively, other materials contemplated for use in the TCO layer 160 include, for example, but not limited by, conductive polymers in the family of 3,4 ethylenedioxythiophene conducting polymers, as well as conducting materials such as fullerenes. Such materials may be prepared as liquid suspensions, and as such may be readily applied and cured.

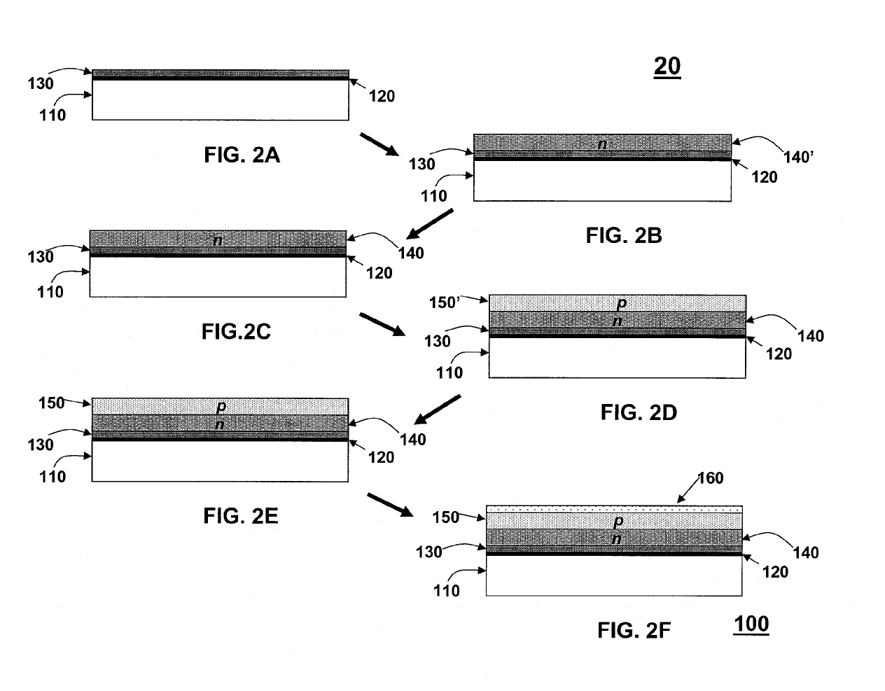

Alternatively, in FIGS. 2A-2F a second method 20 for making a single junction p/n device 100 with embodiments of Group IV semiconductor nanoparticle materials is shown. In method 20, the stepwise deposition and fabrication of single layers of n-doped and p-doped photoconductive thin layers is done. For the stepwise method 20, after the optional insulating layer 120 and the first electrode 130 have been deposited (FIG. 2A), a first Group IV nanoparticle film layer 140′ of the device 100 is deposited, as shown in FIG. 2B. As previously mentioned for the sequential process method 10, this first deposited crystalline Group IV semiconductor nanoparticle layer 140′ is deposited using an embodiment of a Group IV semiconductor n-doped nanoparticle ink or the thin film is then subsequently n-doped. The stepwise procedure 20 varies from the sequential method, in that after the deposition of the n-doped layer 140′, the n-doped nanoparticle layer 140′ is then processed in an inert, substantially oxygen free environment at a selected temperature for an appropriate amount of time, and optionally using pressure, to form an n-doped photoconductive thin-film layer, as shown in FIG. 2C. In FIG. 2D, after the formation of an n-doped photoconductive Group IV semiconductor thin film 140, in the next process step, the second p-doped nanoparticle thin film layer 150′ is deposited using an embodiment of a Group IV semiconductor p-doped nanoparticle ink, or the thin film is the subsequently p-doped, as previously described for the sequential process method 10. In the next step the p-doped nanoparticle thin film layer 150′ is processed in an inert, substantially oxygen free environment to form a p-doped photoconductive Group IV semiconductor thin film 150, as shown in FIG. 2E. Finally, a transparent conductive oxide (TCO) layer 160 is deposited on the p-doped layer to complete the fabrication of a p/n Group IV semiconductor photoconductive device (FIG. 2F).

With respect to the selection of the sequential method 10 in or the stepwise method 20, while it understood that the stepwise method 20 introduces more process steps, it also offers the potential for greater process control. As such, the consideration for which process method to use arises from the embodiment of device that is being fabricated. General considerations for producing multi-layer photoconductive Group IV semiconductor thin films relate to increasing device yield by greatly reducing or eliminating defects which may arise from film discontinuities and contamination.

In that regard, for the sequential method 10, the deposition method is selected so as to prevent the intermixing of particles or dopants or both at junctions. Additionally, the deposition method is selected to reduce or eliminate the accumulation of stress points in the film layers that arise upon sequential deposition. Such stress points in the deposited Group IV nanoparticle thin films may create mechanical discontinuities in the photoconductive thin film layers after processing, yielding them defective thereby. Additionally, the deposited nanoparticle thin films are not mechanically robust until processed to produce the photoconductive thin films. The impact of this is that the nanoparticle thin films of process 10 cannot be readily cleaned of contaminants or treated to remove oxidation using conventional semiconductor thin film processing steps.

However, if such process steps for removal of contaminants or oxide are indicated for embodiments of multi-layer device designs, such process steps may be readily integrated into the stepwise method 20 after the formation of the photoconductive Group IV semiconductor thin films, such as n-doped thin film layer 140 and p-doped thin film layer 150 of device 100 shown in FIG. 1E and FIG. 2F. Moreover, the stepwise process may be used to deposit sequential strata of the same type of Group IV semiconductor nanoparticle ink in order to fabricate a single thin film layer, such as the n-doped thin film layer 140 or the p-doped thin film layer 150 of device 100. Such a method may be effective in repairing mechanical defects, such as pin holes or cracks, formed in a first fabricated stratum by the subsequent deposition of a second stratum of a Group IV semiconductor nanoparticle ink, followed by the stepwise fabrication of the strata. There is a low probability of defects aligning during such a stepwise fabrication of a single layer, thereby serving as a useful process for increasing yield. The ease of application of Group IV nanoparticle inks, providing deposition of a range of thicknesses of Group IV nanoparticle thin films, provides for ready integration of either sequential or stepwise methods into Group IV photoconductive thin film fabrication.

Other considerations for greatly reducing or eliminating defects during the processing of Group IV semiconductor nanoparticle thin films to form photoconductive Group IV semiconductor thin films when using either process method 10 or 20 include: 1.) controlling the processing parameters of temperature and pressure, 2.) optimizing the film thicknesses, and 3.) the selection of the type of Group IV nanoparticle material for a targeted photoconductive Group IV semiconductor thin film.

Controlling the process parameters of temperature and pressure, and optimizing film thickness ensure that structural defects will be minimized or eliminated during processing in order to maximize the yield of functional devices. Generally, it is desirable to select the minimal processing temperature and time for achieving the conversion of the Group IV semiconductor nanoparticle thin films to Group IV semiconductor nanoparticle thin films. This not only has an impact on process costs, but moreover acts to minimize the redistribution of dopant molecules during processing, and may reduce stress defects, as well. In that regard, the use of a ramp rate of the temperature and optionally the pressure conditions may also ensure that the Group IV semiconductor nanoparticle thin films experience no initial untoward thermal or baric stress. Additionally, the appropriate ramp rates of processing parameters ensure evenness of processing conditions throughout the processing apparatus, and hence throughout the devices being processed, also decreasing the probability of inducing stress in devices during processing thereby. Film thickness is optimized to target Group IV nanoparticle film thicknesses that will result in Group IV photoconductive thin films of sufficient thickness to provide the targeted function, but as thin as possible to achieve that result in order to minimize the formation of structural defects during processing.

Embodiments of nanoparticle thin films having specific functionality may be derived from variations of the nanoparticle material crystallinity, composition, size, and shape. More specifically, various embodiments of Group IV semiconductor thin film devices can be fabricated by varying the particle sizes and shapes to adjust the packing density of the deposited Group IV semiconductor nanoparticle thin film, as well as varying the particle composition and size to adjust the fabrication temperature of such deposited thin films, as previously discussed.

For example, in stepwise process 20, the processing temperature for a first Group IV nanoparticle layer in a multi-layer device should have a equivalent or higher processing temperature than any subsequent thin film layer formed, so as to avoid dopant redistribution, and the potential for forming defects at a reforming interface. In order to achieve this, particle size and composition, and combinations thereof may be considered. In this regard, given that there is a direct correlation between nanoparticle size and melting temperature for silicon nanoparticles between the size range of about 1 nm to about 10 nm, then a first thin film layer of a multi-layer device could be formulated using silicon nanoparticles of a larger or equal size than subsequent nanoparticle thin layers. Further, germanium nanoparticles of comparable size to silicon nanoparticles melt at a lower temperature, so where types of nanoparticle materials having more than one type of Group IV semiconductor element are indicated, the melting temperatures of the materials may be exploited. While the example has been given for a first thin layer, one of ordinary skill in the art will recognize that the reasoning extends to each additional thin layers of a multi-layer device, so that for example, given three layers, then the melting temperatures of the layers are such that T₁≧T₂≦T₃. In that regard, for the stepwise processing method 20, melting temperatures of each thin layer in a multi-layer device must be tuned accordingly.

Finally, though the discussion in the above concerning considerations of a sequential processing method 10, and a stepwise processing method 20, combinations of the sequential and the stepwise processing methods may be done. For example, for some multi-layer Group IV photoconductive thin layer devices, a sequential processing method 10 as a high-throughput method for some layers, followed by a stepwise processing method 20 to form a subsequent layer or layers. As given in the previous discussion, the considerations between throughput and control must be considered for the various embodiments of photoconductive Group IV semiconductor thin films.

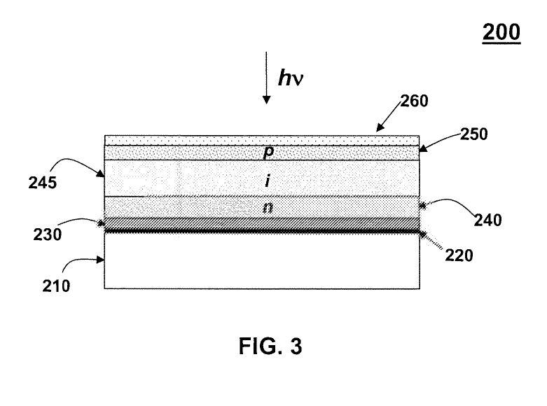

In FIG. 3 is shown an example of a two-layer thin film, such as that of device 100 shown in FIG. 1E and FIG. 2F, which was fabricated using a stepwise process, as described for stepwise process 20. The substrate 110 is a 1″×1″ quartz substrate, upon which a first molybdenum electrode layer 130, which is about 100 nm thick was deposited. For the purpose of illustration, the Group IV semiconductor nanoparticle material for both layers in this example was comprised of silicon nanoparticles of about 8.0 nm in diameter. A silicon nanoparticle ink was prepared from the silicon nanoparticles in an inert environment as a 2 mg/ml solution in chlorobenzene, which was sonicated using a sonication horn at 35% power for 15 minutes. The silicon nanoparticle thin layers were deposited via drop casting, using 340 microliters of ink for each layer. After the deposition of the first thin layer of silicon nanoparticles, a photoconductive silicon thin film 145 was fabricated at between about 600° C. to about 800° C. at a pressure of between about 5×10⁻⁶ to about 7×10⁻⁶ Torr for 8 minutes. A ramp rate of about 300° C./minute to about 400° C./minute was used. After the device was allowed to reach ambient temperature in an inert environment, a second thin layer of silicon nanoparticles was drop cast upon the silicon photoconductive thin layer 145, and processed as described for the first layer of silicon nanoparticles to form a second photoconductive silicon thin film 155. As can be seen in the expanded view shown in the inset, though cast as two layers, the film has the appearance of a continuous single layer film 170.

It is contemplated that multilayer thin films may also be formed using a variety of deposition methods, for example, but not limited by, roll coating, slot die coating, gravure printing, flexographic drum printing, and ink jet printing methods, or combinations thereof. Multilayer films such as those shown in FIG. 3, may be formed using spin casting, in which, for example, a dispersion of about 20 mg/ml solution of silicon nanoparticles of about 8.0 nm in diameter is prepared in a solution of chloroform/chlorobenzene (4:1). The surface of a quartz substrate is covered with the nanoparticle dispersion, and spun at 500 rpm for about one minute. The resulting film thickness is about 1 micron. Either the sequential method 10 or the stepwise method 20 may be used to add additional layers using spin casting. For instance, if the sequential method 10 is used, then the step for forming the first layer is repeated for subsequent layers without any fabrication step until all layers for a targeted device design have been deposited. For the stepwise method 20, then a fabrication step would be done in between the deposition of each layer deposited using spin casting. An alternative method would be to have a baking step, instead of a fabrication step, in between the deposition of the nanoparticles. Such a baking step would be a process step of shorter duration and lower temperature than a fabrication step, and would act to make the deposited film layer more mechanically robust before the deposition of a subsequent layer. For example, the film may be baked in an inert environment for between about 2-10 minutes at between about 200° C. to about 300° C. before proceeding to deposit a subsequent layer of Group IV semiconductor nanoparticles.

As one of ordinary skill in the art is apprised, photoconductive devices generally consist of multiple layers of semiconductor materials, as shown for device 100 in FIG. 1E. However, it should be noted that a single layer device fabricated from single type of Group IV semiconductor nanoparticle material has utility for devices not requiring high efficiency, and hence not high power. Such devices include, but are not limited by consumer devices, such as watches, calculators, and phones, as well as devices such as photodetectors.

In that regard, embodiments of devices comprising a single layer of a Group IV semiconductor thin film could be fabricated in a fashion similar to that of device 100 shown in FIG. 1E and FIG. 2F. In such embodiments, a single layer of a variety of types of crystalline Group IV semiconductor nanoparticles could be used to produce a crystalline thin film layer between the first electrode 130 and the second electrode 160. For example, nanoparticles of crystalline silicon, germanium, and alpha-tin, or combinations thereof could be used to form a single thin film layer, where for various embodiments, the particle sizes and shapes could be varied. In a similar fashion, other embodiments of a single layer of a Group IV semiconductor material comprising amorphous Group IV semiconductor nanoparticles could be used between the first electrode 130 and the second electrode 160. Still other embodiments of single-layer Group IV semiconductor thin film devices can be fabricated using combinations of types of crystalline and amorphous Group IV semiconductor nanoparticle materials, in which microcrystallite Group IV semiconductor materials are embedded in amorphous Group IV semiconductor materials. For example, nanoparticles of crystalline silicon, germanium, and alpha-tin, or combinations thereof could be mixed with amorphous silicon, germanium, and alpha-tin, or combinations thereof, and processed to form a single microcrystalline thin film layer. As has been described for the other embodiments of single-junction Group IV semiconductor thin film devices, various embodiments of Group IV semiconductor thin film devices can be fabricated by varying the particle sizes and shapes to impact the packing of the deposited Group IV semiconductor nanoparticle thin film, as well as varying the particle composition and size to impact fabrication temperature of such deposited thin films, as previously discussed. For embodiments of Group IV single layer photoconductive devices, the electric field which develops in such the devices due to the work functions of the electrode materials in contact with the Group IV photoconductive layer, or from heterojunctions formed in the layer using Group IV semiconductor nanoparticle blends.

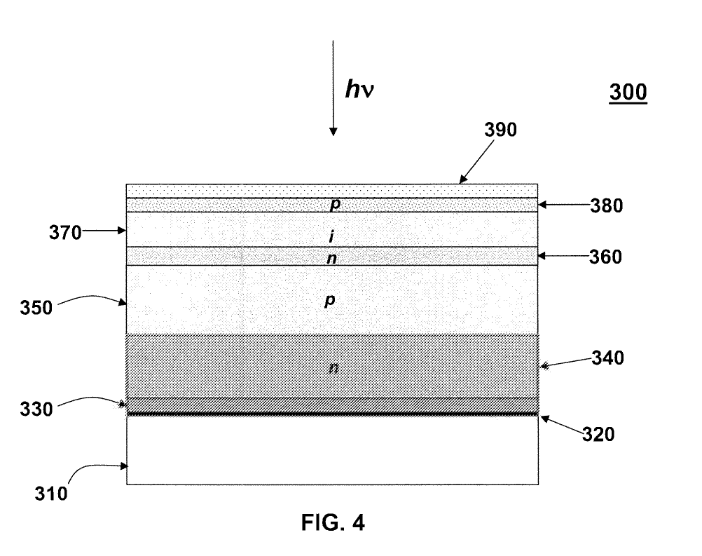

In FIG. 4, another embodiment of a single junction device that may be fabricated using process methods such as 10 and 20, and combinations thereof is shown. For photoconductive device 200 of FIG. 4, considerations for substrate 210, insulating layer 220, and first electrode 230, for photoconductive device 200 are the same as for that given for photoconductive device 100 shown in FIG. 1E and FIG. 2F. Upon first electrode layer 230, a first n-doped Group IV semiconductor thin layer 240 is shown, upon which an intrinsic layer Group IV semiconductor thin layer 245 is shown, and finally upon which a Group IV semiconductor p-doped thin layer 250 is shown. For device 200 of FIG. 4, the crystallinity of the Group IV nanoparticle material may vary from amorphous to polycrystalline, and combinations thereof. Finally, a transparent conductive oxide (TCO) layer 260 of between about 100 nm to about 200 nm is deposited on the p-doped layer to complete the fabrication of a p/n Group IV semiconductor photoconductive device.

For example, the first n-doped layer 240 is deposited using an embodiment of a Group IV semiconductor n-doped nanoparticle ink formulated from amorphous or crystalline silicon nanoparticles, and combinations thereof. Alternatively, thin film 240 is formed using a nanoparticle ink formulated from amorphous or crystalline silicon nanoparticles, and combinations thereof, and subsequently n-doped using, for example, standard procedures for thin film doping with phosphine, arsine, or phosphorous oxychloride. The n-doped photoconductive layer 240 formed after processing is between about 10 nm to about 100 nm in thickness. The intrinsic photoconductive layer 245 may be formed from undoped amorphous or crystalline silicon nanoparticles, or combinations thereof, and is between about 0.5 microns to about 3.0 microns in thickness. Intrinsic photoconductive layer 245 may also be formed using a silicon nanoparticle ink specifically formulated using a blend of silicon nanoparticles, and an appropriate amount of a p-doped silicon nanoparticles, so as to compensate for contaminants, such as oxygen, which may then act to create undesirable trap states. The p-doped photoconductive layer 250 is deposited using an embodiment of a Group IV semiconductor p-doped nanoparticle ink formulated from amorphous or crystalline silicon nanoparticles, and combinations thereof. Alternatively, thin film 250 is formed using a nanoparticle ink formulated from amorphous or crystalline silicon nanoparticles, and combinations thereof, and subsequently p-doped using, for example, standard procedures for thin film doping with boron diflouride, trimethyl borane, or diborane. The p-doped photoconductive layer 250 is between about 10 nm to about 100 nm in thickness. Finally the transparent conductive oxide (TCO) layer is about 100 nm in thickness. Alternatively, for all layers (240, 245, 250) of device 200 shown in FIG. 4, the deposited layers of nanoparticles may be a mixture of amorphous and crystalline silicon nanoparticles. Then, depending on the proportion of crystalline to amorphous nanoparticles, as well as the processing parameters, embodiments of microcrystalline photoconductive thin films may be formed. Additionally, various embodiments of Group IV semiconductor thin film devices can be fabricated by varying the particle sizes and shapes to impact the packing of the deposited Group IV semiconductor nanoparticle thin film, as well as varying the particle composition and size to impact fabrication temperature of such deposited thin films, as previously discussed.

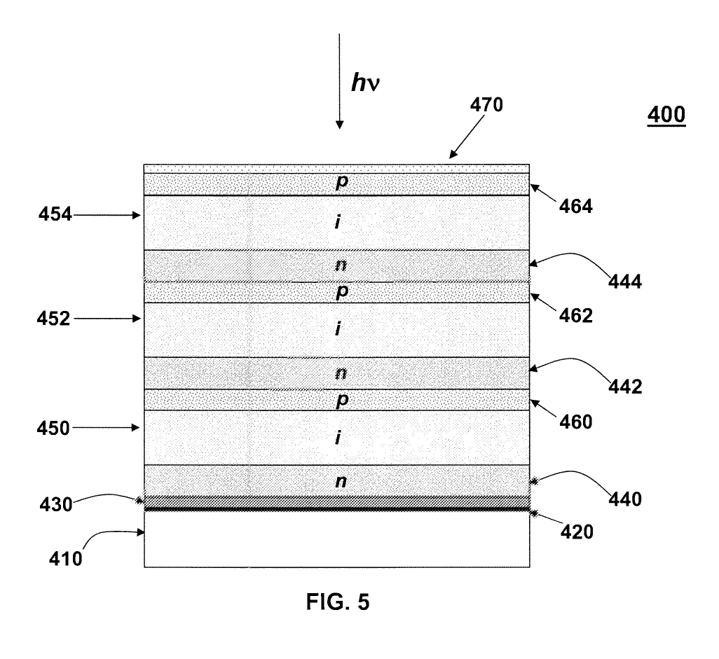

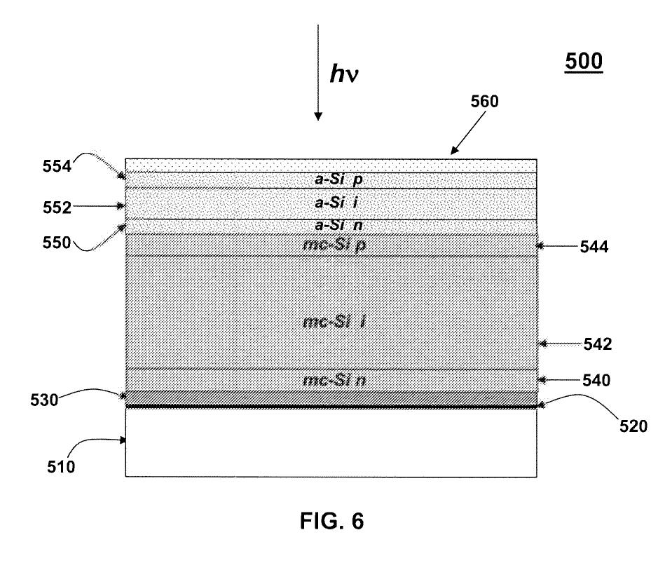

Additionally, using process methods such as 10 and 20, and combinations thereof, tandem devices having greater complexity may be fabricated. FIGS. 5-7 are given as examples of embodiments of some tandem devices that can be readily fabricated using process methods 10 and 20, and combinations thereof. For example, FIG. 5 depicts a tandem device that combines a single junction p/n device 100 of FIG. 1E and FIG. 2F, and a single junction p/i/n device 200 of FIG. 4. Similarly, FIG. 6 combines three p/i/n devices 200 of FIG. 4. As previously discussed, the nanoparticles for the p/n configuration are crystalline in nature, while the nanoparticles for the p/i/n configuration are amorphous or crystalline, or combinations thereof. In this regard, embodiments of tandem structures take advantage of the stability and efficiency of crystalline Group IV semiconductor materials, and the higher absorptivity in the visible region of the electromagnetic spectrum of amorphous Group IV semiconductor materials.

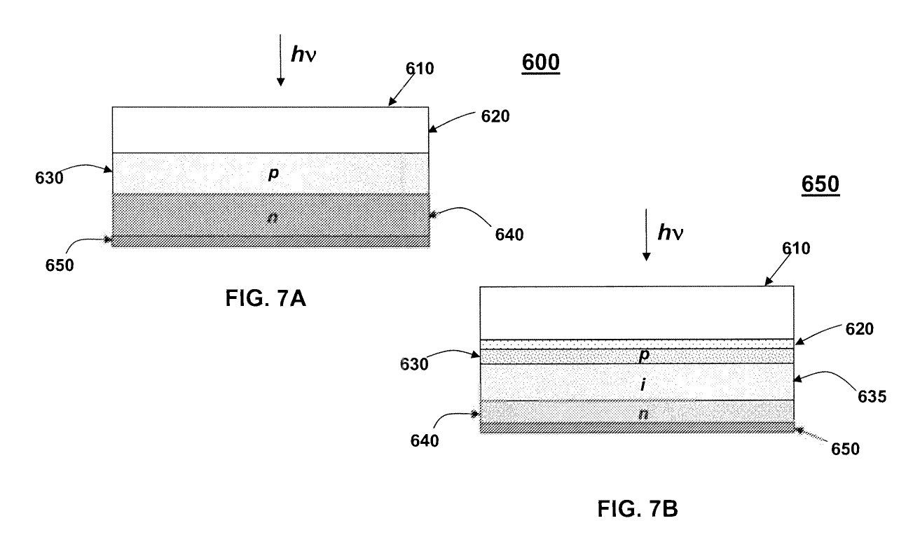

FIG. 7 depicts still another embodiment of a tandem photoconductive device 500, which takes advantage of the combined characteristics of amorphous and crystalline materials. In FIG. 7, layers 540, 542, and 544 are photoconductive n-doped, intrinsic and p-doped microcrystalline Group IV semiconductor thin films, respectively. For the intrinsic layer 542, as previously discussed, the deposited layer of nanoparticles may be a mixture of amorphous and crystalline silicon nanoparticles. Depending on the proportion of crystalline to amorphous nanoparticles formulated in the Group IV semiconductor nanoparticle ink, as well as the processing parameters, intrinsic layer 542 may be fabricated to form embodiments of microcrystalline photoconductive intrinsic thin films. Intrinsic photoconductive layer 542 may also be formed using a silicon nanoparticle ink specifically formulated using a blend of silicon nanoparticles, and an appropriate amount of a p-doped silicon nanoparticles, so as to compensate for contaminants, such as oxygen, which may then act to create undesirable trap states. For the doped layers (540, 544, 550, 554) of device 500, the mixture of amorphous and crystalline silicon nanoparticles used to form such layers are either doped amorphous silicon nanoparticles, or doped crystalline silicon nanoparticles or both. Alternatively, the amorphous and crystalline nanoparticle thin film is then subsequently doped using standard procedures, as previously discussed. The thickness of the absorbing intrinsic microcrystalline layer 542 is about 0.2 micron to about 3 microns, while the microcrystalline n-doped 540 and p-doped 544 layers that are critical for charge separation are about 10 nm to about 50 nm. In a similar fashion, the thickness of the absorbing intrinsic amorphous layer 552 is about 100 nm to about 300 nm, while the amorphous n-doped 550 and p-doped 554 layers that are critical for charge separation are about 10 nm to about 50 nm. Finally, a transparent conductive oxide (TCO) layer 560 of between about 100 nm to about 200 nm is deposited on the p-doped layer to complete the fabrication of a p/n Group IV semiconductor photoconductive device.

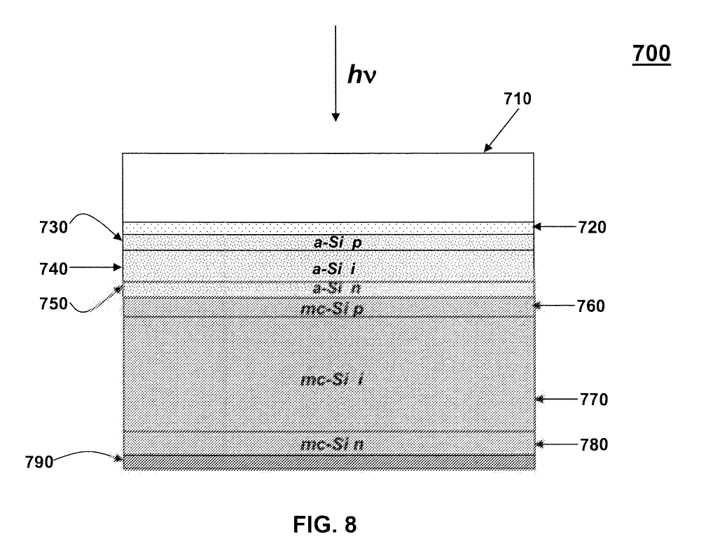

All the photoconductive thin film devices so far discussed have the substrate shown as the most distal layer upon which the electromagnetic radiation would impinge. However, one of ordinary skill in the art would recognize that devices such as those shown in FIG. 8A and FIG. 8B, where the light first impinges on the substrate are also devices that may readily be fabricated using process methods such as 10 and 20, and combinations thereof.

In FIG. 8A, a single junction p/n device is shown, while in FIG. 8B, a single junction p/i/n device is shown. In comparing these devices to those of device 100 of FIG. 1E or FIG. 2F and device 200 of FIG. 4, it can be seen that variations of device 600 shown in FIG. 8A and device 650 in FIG. 8B, are essentially inverted structures of device 100 and device 200, respectively. In that regard, the substrate 610 and TCO layer 620 may be selected as previously described for substrate 110 of FIG. 1E and FIG. 2F. However, the transparent conductive oxide (TCO) layer 620 degrades above about 400° C. and is deposited on the substrate prior to the fabrication of the Group IV nanoparticles to form photoconductive thin films. As such, the devices shown in FIG. 8A and FIG. 8B would be fabricated at the lower end of the range stated previously, or at about 400° C. In this regard, as previously discussed nanoparticle size and composition may be exploited to decrease the processing temperature for forming a photoconductive Group IV semiconductor thin layer from a thin layer of Group IV semiconductor nanoparticle materials.

For example, in FIG. 8B, an embodiment of a nanoparticle ink could be formulated using amorphous silicon nanoparticles of about 5.0 m in diameter, blended with crystalline germanium nanoparticles of about 4.0 nm in diameter. Upon substrate 610, a TCO layer 620 of between about 100 nm to about 200 nm would be deposited. The nanoparticle ink used for the deposition of doped layers 630 and 640 of p/i/n device 600 would be formulated using amorphous silicon and crystalline germanium nanoparticles, as well as either doped amorphous silicon nanoparticles, or doped crystalline germanium nanoparticles or both. Alternatively, the thin film amorphous and crystalline nanoparticle film is then subsequently doped using standard procedures, as previously discussed. The nanoparticle ink used for the deposition of the intrinsic layer 635 of p/i/n device 600 would be formulated using amorphous silicon and crystalline germanium nanoparticles, or also be formed using a nanoparticle ink specifically formulated using a blend of Group IV nanoparticles, and an appropriate amount of a p-doped Group IV nanoparticles, so as to compensate for contaminants, such as oxygen, which may then act to create undesirable trap states Either the sequential 10 or stepwise 20 processing method may be used. The thickness of the photoconductive thin intrinsic film layer 635 is between about 0.2 microns to about 3.0 microns in thickness. The p-doped photoconductive layer 630 is between about 10 nm to about 100 nm in thickness, while the n-doped photoconductive layer 640 is between about 10 nm to about 100 nm in thickness. The second electrode 650 is selected from conductive materials, such as, for example, aluminum, molybdenum, chromium, titanium, nickel, and platinum, and is between about 10 nm to about 1000 nm in thickness for the various embodiments of a Group IV photoconductive, such as that shown in FIG. 8B.

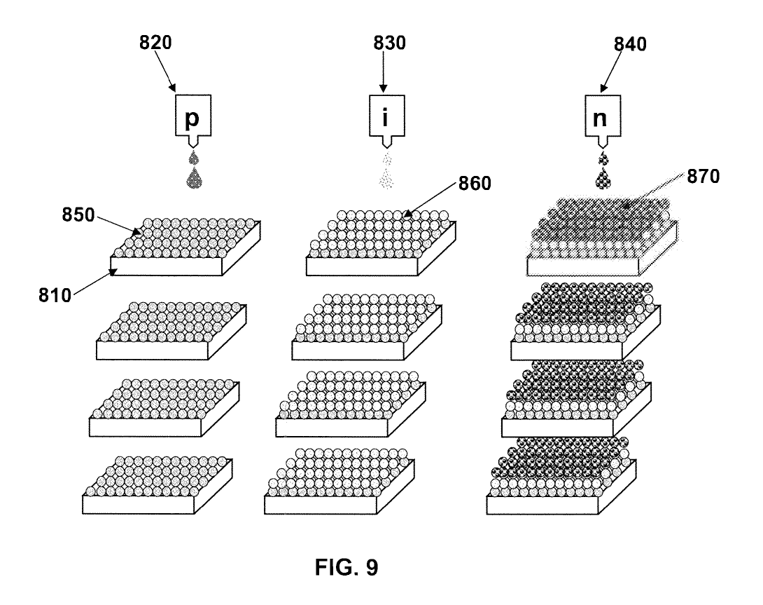

Finally, Group IV photoconductive devices of greater complexity are also possible for devices in which the light first impinges on the substrate. Shown in FIG. 9, an embodiment of such a device is shown, which is similar in structure to that of FIG. 7. The considerations of the choice of substrate and TCO are the same as previously discussed for those of device 100 of FIG. 1E or FIG. 2F. On substrate 710, a TCO layer 720 of between about 0.5 micron to about 1 micron is deposited. The thickness of the absorbing intrinsic amorphous layer 740 is about 100 nm to about 300 nm, while the amorphous p-doped 730 and n-doped 750 layers that are critical for charge separation are about 10 nm to about 50 nm. The thickness of the absorbing intrinsic microcrystalline layer 770 is about 0.2 micron to about 3 microns, while the microcrystalline p-doped 760 and n-doped 780 layers that are critical for charge separation are about 10 nm to about 50 nm. In other embodiments of device 700 of FIG. 9, the intrinsic layer 770 may be fabricated using mixtures of amorphous silicon nanoparticles and amorphous germanium nanoparticles. In still other embodiments of device 700 of FIG. 9, the intrinsic layer 770 may be fabricated using mixtures of amorphous silicon nanoparticles and crystalline germanium nanoparticles.

Moreover, it is contemplated that combinations of types of processing can be integrated to create embodiments of Group IV photoconductive devices. For example, plasma enhanced chemical vapor deposition (PECVD) can currently deposit crystalline hydrogen terminated silicon thin films at the rate of between about 0.1 to 5 Å/s. While the quality of the quality of the crystalline material is high, the process suffers from a low film deposition rate, increasing the cost of photoconductive thin films fabricated thereby. For example, given the upper end of the intrinsic layer film thickness of 3 microns, even at the highest rate of deposition, this would require about 2 hours of PECVD processing to deposit such a layer. In contrast, the deposition of a 3 micron layer of nanoparticles, followed by fabrication to produce a Group IV photoconductive thin film layer may be about only 10% of the time. Accordingly, the combination of the PECVD process and processes disclosed herein may be used to fabricate embodiments of Group IV photoconductive devices.

For example, for embodiments of device 500 of FIG. 7 and embodiments of device 700 of FIG. 9, as previously mentioned, the p-doped and n-doped layers of these devices are for charge separation, while the intrinsic layers are for photon adsorption. In that regard, intrinsic layers 542 and 552 of device 500, and layers 740 and 770 of device 700 may be fabricated as described previously. However, for n-doped layers 540 and 550, as well as p-doped layers 544 and 554 of device 500, and n-doped layers 730 and 760, as well as p-doped layers 750 and 780 of device 700, these layers could be fabricated using a PECVD process.

From what has been previously discussed, the utility realized in fabricating native Group IV photoconductive thin films from embodiments of Group IV semiconductor nanoparticle ink formulations includes, but is not limited by: 1.) Control over formulating inks that selectively blend the appropriate particle sizes and shapes to achieve a targeted nanoparticle pack density in a deposited thin film. 2.) Control over formulating inks that have the appropriate amount of doped nanoparticle to undoped nanoparticle in order to achieve the desired performance for a specific doped layer in a targeted device embodiment. 3.) Control over formulating inks that are appropriately adjusted with dopant levels to compensate for contaminants in order to achieve the desired performance for a specific intrinsic layer in a targeted device embodiment. 4.) Control over formulating Group IV semiconductor nanoparticle inks for adjusting the photon adsorption over a wider range of the electromagnetic spectrum. 5.) Capability to rapidly deposit multiple layers over a range of thicknesses, resulting in reduced fabrication time, as well as increase in yield through defect control.

Additionally, the use of ink compositions of Group IV semiconductor nanoparticles lends both the sequential process 10 of FIGS. 1A-1E, and stepwise process 20 of FIGS. 2A-2F amenable to high-volume manufacturing processes. As previously mentioned, it is contemplated that multilayer thin films may also be formed using a variety of deposition methods, for example, but not limited by roll coating, slot die coating, gravure printing, flexographic drum printing, and ink jet printing methods, or combination thereof.

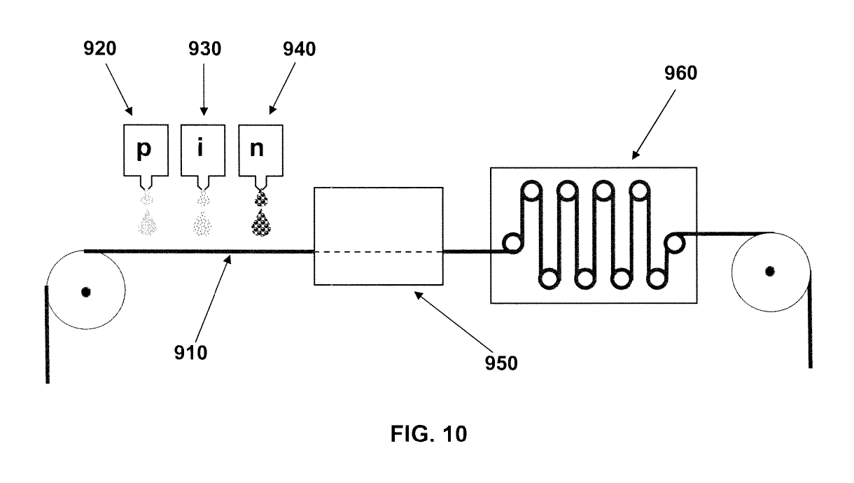

For example, a high volume batch process, such as that indicated in FIG. 10 may be used when processing rigid substrates. Exemplary rigid substrates include silicon dioxide-based substrates such as, but are not limited by, quartz, and glasses, for example, soda lime and borosilicate glasses. Here, using a sequential process method, such an embodiment of sequential process method 10 of FIGS. 1A-1E, a plurality of rigid substrates 810 may be taken through successive deposition steps using various embodiments of Group IV semiconductor nanoparticle inks 820, 830, and 840. The plurality of substrates 810 having deposited nanoparticle thin films 850, 860, and 870 may then be fabricated to produce embodiments of Group IV photoconductive thin films and thin film devices. Alternatively, in between the deposition of each Group IV semiconductor nanoparticle thin film, the plurality substrates 810 having a newly deposited nanoparticle thin film may be processed using a stepwise process method, such as an embodiment of stepwise process method 20 of FIGS. 2A-2F.

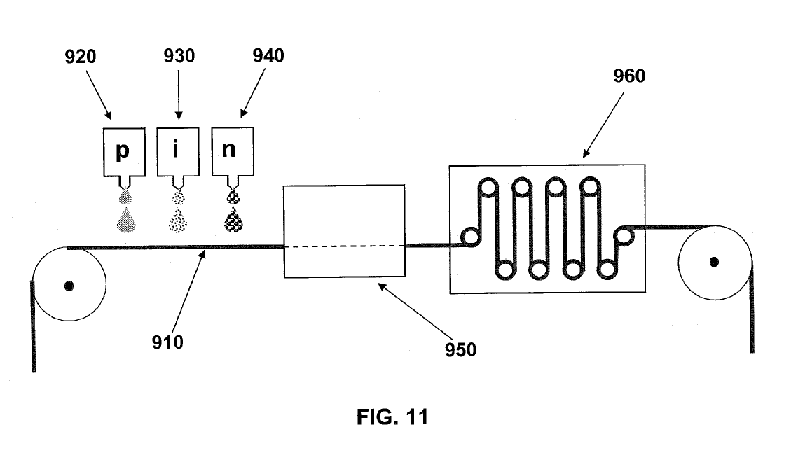

When using flexible substrates, such as stainless steel sheet or heat-durable polymers, such as polyimides and aromatic fluorene-containing polyarylates, a high volume web process, such as that indicated in FIG. 11 may be used. In FIG. 11, embodiments of ink formulations 920, 930, and 940 may be used to dynamically deposit layers of Group IV semiconductor nanoparticle thin films on a roll of substrate 910. In such a sequential method, the deposited thin films are then fabricated in chamber 950, to form embodiments of Group IV photoconductive films. In chamber 960, processing steps, such as hydrogenation of the fabricated photoconductive thin film formed in chamber 950 may be performed. The serpentine pattern of rolls in chamber 960 significantly decreases processing time by significantly increasing the total length of substrate that can be processed in a unit time. Though not shown in FIG. 11, it is possible to adapt such a web process to a stepwise method by having a fabrication chamber 950 between each deposition step of Group IV semiconductor nanoparticles on substrate 910.

While principles of the disclosed photoconductive Group TV semiconductor thin film devices and methods for making such devices have been described in connection with specific embodiments, it should be understood clearly that these descriptions are made only by way of example and are not intended to limit the scope of what is disclosed. In that regard, what has been disclosed herein has been provided for the purposes of illustration and description. It is not intended to be exhaustive or to limit what is disclosed to the precise forms described. Many modifications and variations will be apparent to the practitioner skilled in the art. What is disclosed was chosen and described in order to best explain the principles and practical application of the disclosed embodiments of the art described, thereby enabling others skilled in the art to understand the various embodiments and various modifications that are suited to the particular use contemplated. It is intended that the scope of what is disclosed be defined by the following claims and their equivalence.

1-20. (canceled)

21. A device for generating an electron-hole pair from a photon, comprising:
a substrate;
a first electrode formed above the substrate;
a first thin film formed on the first electrode from a first ink, the first ink further including a first set of doped Group IV nanoparticles;
a second thin film formed on the first thin film from a second ink, the second ink further including a set of intrinsic Group IV nanoparticles;
a third thin film formed on the second thin film from a third ink, the third ink further including a second set of doped Group IV nanoparticles;
a second electrode formed on the third thin film, wherein when the photon is absorbed by the device, the electron-hole pair is collected.

22. The device of claim 21, wherein the first set of doped Group IV nanoparticles includes n-doped particles and the second set of doped Group IV nanoparticles includes p-doped particles.

23. The device of claim 21, wherein the first set of doped Group IV nanoparticles includes p-doped particles and the second set of doped Group IV nanoparticles includes n-doped particles.

24. The device of claim 21, wherein at least one of the first set of doped Group IV nanoparticles, the set of intrinsic Group IV nanoparticles, and the second set of doped Group IV nanoparticles includes one of silicon nanoparticle, germanium nanoparticle, and alpha-tin nanoparticle.

25. The device of claim 21, wherein the second electrode is a TCO, the TCO having a third thickness of between about 100 nm and about 200 nm.

26. The device of claim 21, wherein the first thin film and the third thin film each has a first thickness of between about 10 nm and 100 nm.

27. The device of claim 21, wherein the second thin film has a second thickness of between about 0.5 microns and about 3.0 microns.

28. A device for generating a plurality of electron-hole pairs from a photon, comprising:
a substrate;
a first electrode formed above the substrate;
an n-doped microcrystalline layer formed on the first electrode from a first ink;
a p-doped microcrystalline layer formed on the n-doped microcrystalline layer from a second ink;
an n-doped amorphous layer formed on the p-doped microcrystalline layer from a third ink;
an intrinsic amorphous layer formed on the n-doped amorphous layer from a fourth ink;
a p-doped amorphous layer formed on the intrinsic amorphous layer from a fifth ink;
a second electrode formed on the p-doped amorphous layer; wherein when the photon is absorbed by the device, an electron-hole pair is collected.

29. The device of claim 28, wherein at least one of the p-doped microcrystalline layer, the n-doped microcrystalline layer has a first thickness of between about 10 nm and about 50 nm.

30. The device of claim 28, wherein the intrinsic amorphous layer has a second thickness of between about 0.1 micron and about 3 microns.

31. The device of claim 28, wherein at least one of the p-doped amorphous layer and the n-doped amorphous layer has a first thickness of between about 10 nm and about 50 nm.

32. The device of claim 28, wherein the second electrode is TCO.

33. The device of claim 32, wherein the TCO has a third thickness of between about 100 nm and about 200 nm.

34. A device for generating a plurality of electron-hole pairs from a photon, comprising:
a substrate;
a first electrode formed above the substrate;
a p-doped microcrystalline layer formed on the first electrode from a first ink;
an n-doped microcrystalline layer formed on the p-doped microcrystalline layer from a second ink;
a p-doped amorphous layer formed on the n-doped microcrystalline layer from a third ink;
an intrinsic amorphous layer formed on the p-doped amorphous layer from a fourth ink;
an n-doped amorphous layer formed on the intrinsic amorphous layer from a fifth ink;
a second electrode formed on the p-doped amorphous layer; wherein when the photon is absorbed by the device, an electron-hole pair is generated.

35. The device of claim 34, wherein at least one of the p-doped microcrystalline layer, the n-doped microcrystalline layer has a first thickness of between about 10 nm and about 50 nm.

36. The device of claim 34, wherein the intrinsic amorphous layer has a second thickness of between about 0.1 micron and about 3 microns.

37. The device of claim 34, wherein at least one of the p-doped amorphous layer and the n-doped amorphous layer has a first thickness of between about 10 nm and about 50 nm.

38. The device of claim 34, wherein the second electrode is TCO.

39. The device of claim 38, wherein the TCO has a third thickness of between about 100 nm and about 200 nm.

40. A device for generating a plurality of electron-hole pairs from a photon, comprising:
a substrate;
a first electrode formed above the substrate;
a first microcrystalline layer formed on the first electrode from a first ink, wherein the first microcrystalline layer includes doped Group IV nanoparticles;
a second microcrystalline layer formed on the first microcrystalline layer from a second ink, wherein the second microcrystalline layer includes intrinsic Group IV nanoparticles;
a third microcrystalline layer formed on the second microcrystalline layer from a third ink, wherein the third microcrystalline layer includes doped Group IV nanoparticles;
a first amorphous layer formed on the third microcrystalline layer from a fourth ink, wherein the first amorphous layer includes doped Group IV nanoparticles;
a second amorphous layer formed on the first amorphous layer from a fifth ink, wherein the second amorphous layer includes intrinsic Group IV nanoparticles;
a third amorphous layer formed on the second amorphous layer from a sixth ink, wherein the third amorphous layer includes doped Group IV nanoparticles;
a second electrode formed on the third amorphous layer; wherein when the photon is absorbed by the device, an electron-hole pair is generated.

41. The device of claim 40, wherein at least one of the first microcrystalline layer, and the second microcrystalline layer has a first thickness of between about 10 nm and about 50 nm.

42. The device of claim 41, wherein the second microcrystalline layer has a second thickness of between about 100 nm and about 300 nm.

43. The device of claim 40, wherein at least one of the first amorphous layer and the third amorphous layer has a third thickness of between about 10 nm and about 50 nm.

44. The device of claim 41, wherein the second amorphous layer has a fourth thickness of between about 0.1 micron and about 3 microns.

45. The device of claim 40, wherein the second electrode is TCO.

46. The device of claim 45, wherein the TCO has a third thickness of between about 100 nm and about 200 nm.

47. A device for generating a plurality of electron-hole pairs from a photon, comprising:
a substrate;
a first electrode formed above the substrate;
a first doped layer formed on the first electrode from a first ink, the first ink including a first set of silicon nanoparticles and a first set of germanium nanoparticles;
a second intrinsic layer formed on the first doped layer from a second ink, the second ink including a second set of silicon nanoparticles and a second set of germanium nanoparticles;
a third doped layer formed on the second intrinsic layer from a third ink, the third ink including a third set of silicon nanoparticles and a third set of germanium nanoparticles;
a second electrode formed on the third doped layer; wherein when the photon is absorbed by the device, an electron-hole pair is generated.

48. The device of claim 47, wherein at least one of the first set of silicon nanoparticles, the second set of silicon nanoparticles, and the third set of silicon nanoparticles has a first diameter of about 5.0 nm.

49. The device of claim 47, wherein at least one of the first set of germanium nanoparticles, the second set of germanium nanoparticles, and the third set of germanium nanoparticles is about 4.0 nm.

50. The device of claim 47, wherein the first doped layer is n-doped and the third doped layer is p-doped.

51. The device of claim 47, wherein the first doped layer is p-doped and the third doped layer is n-doped.
